(19) United States
(12) Patent Application Publication
(10) Pub. No.: US 2010/0302735 A1
(43) Pub. Date: Dec. 2, 2010

(54) ELECTRONIC APPARATUS

(75) Inventors: Norihiro ISHII, Akishima-shi (JP); Yuuji IWASAKI, Ome-shi (JP)

Correspondence Address: KNOBBE MARTENS OLSON & BEAR LLP, 2040 MAIN STREET, FOURTEENTH FLOOR, IRVINE, CA, 92614, US

(73) Assignee: KABUSHIKI KAISHA TOSHIBA, Tokyo (JP)

(21) Appl. No.: 12/853,185

(22) Filed: Aug. 9, 2010

Related U.S. Application Data
(63) Continuation of application No. 12/501,180, filed on Jul. 10, 2009.

(30) Foreign Application Priority Data
Oct. 22, 2008 (JP) 2008-272374

(51) Int. Cl. H05K 7/20

(52) U.S. Cl. 361/701

(57) ABSTRACT

According to one embodiment, an electronic apparatus includes a housing, a circuit board contained in the housing, an integrated-circuit component mounted on the circuit board, a member for heat radiation opposed to the integrated-circuit component and thermally connected to the integrated-circuit component, a sheet metal member which fixes the member for heat radiation, and an electronic component mounted on the circuit board. The sheet metal member includes a main part opposed to the member for heat radiation, and a plurality of leg parts fixed to the circuit board. One leg part of the plurality of leg parts extends from the main part over the electronic component, and is fixed to the circuit board at a position which is farther from the integrated-circuit component than the electronic component is.

### CROSS-REFERENCE TO RELATED APPLICATIONS

This application is a continuation of U.S. patent application Ser. No. 12/501,180, filed Jul. 10, 2009, which is based upon and claims the benefit of priority from Japanese Patent Application No. 2008-272374, filed Oct. 22, 2008, the entire contents of which are incorporated herein by reference.

### BACKGROUND

1. Field

One embodiment of the present invention relates to an electronic apparatus provided with a heat radiation structure.

2. Description of the Related Art

Many electronic apparatuses are provided with a heat radiation structure for promoting cooling of an integrated-circuit component.

Jpn. Pat. Appln. KOKAI Publication No. 10-173113 discloses a heat radiation structure provided with a heat sink. In this heat radiation structure, a heat sink is provided on a top surface of an LSI package, with a thermally-conductive rubber sheet located therebetween. A sheet metal member for fastening the heat sink is fixed to a circuit board in the vicinity of the LSI package.

Incidentally, when an electronic apparatus is dropped onto a surface of a desk or floor by accident, there is the possibility of the circuit board in the electronic apparatus being distorted, and the integrated-circuit components mounted on the circuit board being broken.

### BRIEF DESCRIPTION OF THE SEVERAL VIEWS OF THE DRAWINGS

A general architecture that implements the various feature of the invention will now be described with reference to the drawings. The drawings and the associated descriptions are provided to illustrate embodiments of the invention and not to limit the scope of the invention.

FIG. 1 is an exemplary perspective view of a digital media player according to an embodiment of the present invention;

FIG. 2 is an exemplary perspective view showing a back wall of the digital media player shown in FIG. 1;

FIG. 3 is an exemplary cross-sectional view of the digital media player shown in FIG. 1;

FIG. 4 is an exemplary perspective view of the circuit board and sheet metal member shown in FIG. 3;

FIG. 5 is an exemplary plan view of the circuit board and sheet metal member shown in FIG. 3;

FIG. 6 is an exemplary plan view of the circuit board shown in FIG. 3;

FIG. 7 is an exemplary enlarged plan view of an area of the circuit board shown in FIG. 6 encircled by a line F7;

FIG. 8 is an exemplary enlarged plan view of an area of the circuit board shown in FIG. 6 encircled by a line F8;

FIG. 9 is an exemplary cross-sectional view of the circuit board and sheet metal member shown in FIG. 5 taken along line F9-F9;

FIG. 10 is an exemplary cross-sectional view of the circuit board and sheet metal member shown in FIG. 5 taken along line F10-F10;

FIG. 11 is an exemplary cross-sectional view of the circuit board and sheet metal member shown in FIG. 5 taken along line F11-F11; and

FIG. 12 is an exemplary cross-sectional view of the circuit board and sheet metal member shown in FIG. 11 taken along line F12-F12.

### DETAILED DESCRIPTION

Various embodiments according to the invention will be described hereinafter with reference to the accompanying drawings. In general, according to one embodiment of the invention, an electronic apparatus comprises a housing, a circuit board contained in the housing, an integrated-circuit component mounted on the circuit board, a member for heat radiation opposed to the integrated-circuit component and thermally connected to the integrated-circuit component, a sheet metal member which fixes the member for heat radiation, and an electronic component mounted on the circuit board. The sheet metal member comprises a main part opposed to the member for heat radiation, and a plurality of leg parts fixed to the circuit board. One leg part of the plurality of leg parts extends from the main part over the electronic components, and is fixed to the circuit board at a position which is farther from the integrated-circuit component than the electronic component is.

An embodiment of the present invention will be described below on the basis of drawings of a digital media player to which the present invention is applied.

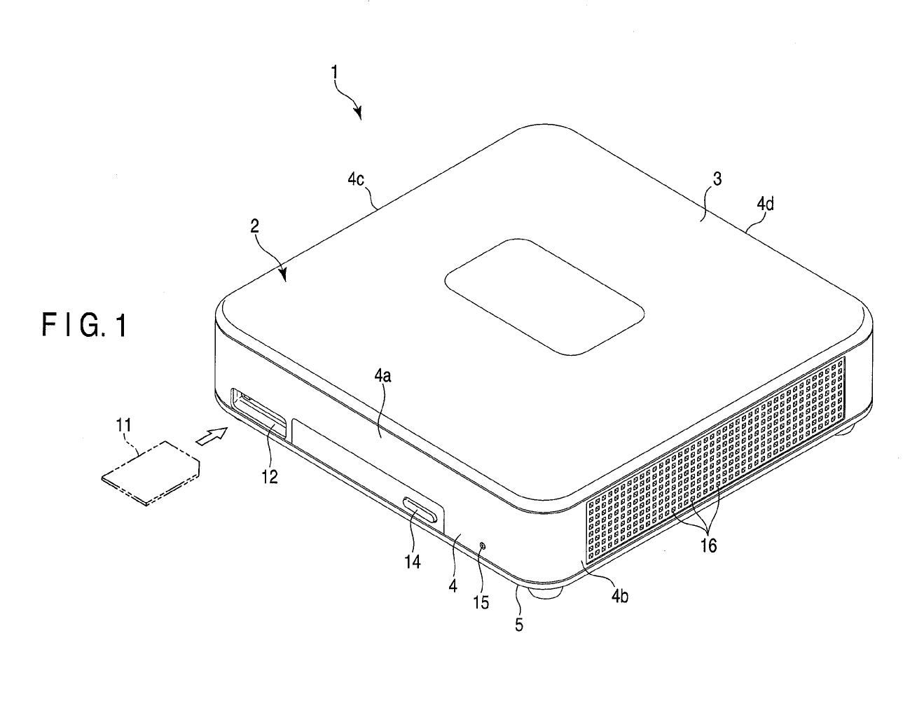

FIGS. 1 to 12 disclose a digital media player 1 as an electronic apparatus according to an embodiment of the present invention. As shown in FIG. 1, the digital media player 1 is provided with a housing 2 having a flat box-like shape. The housing 2 comprises an upper wall 3, peripheral wall 4, and lower wall 5. The peripheral wall 4 comprises a front wall 4a, a left side wall 4b, right side wall 4c, and back wall 4d.

As shown in FIG. 1, an insertion opening section 12 into which a memory card 11 is inserted is provided in the front wall 4a. A memory card slot 13 is provided at the back of the insertion opening section 12. An example of the memory card 11 is a Secure Digital (SD) memory card. It should be noted that the type of the memory card 11 is not limited to the above example, and various types of memory cards are applicable. Further, a power button 14 and reset button 15 are provided in the front wall 4a.

As shown in FIG. 1, a plurality of heat-radiating hole parts 16 are provided in the left side wall 4b in a lattice-like form. Similarly, a plurality of heat-radiating hole parts 16 are provided in the right side wall 4c in a lattice-like form.

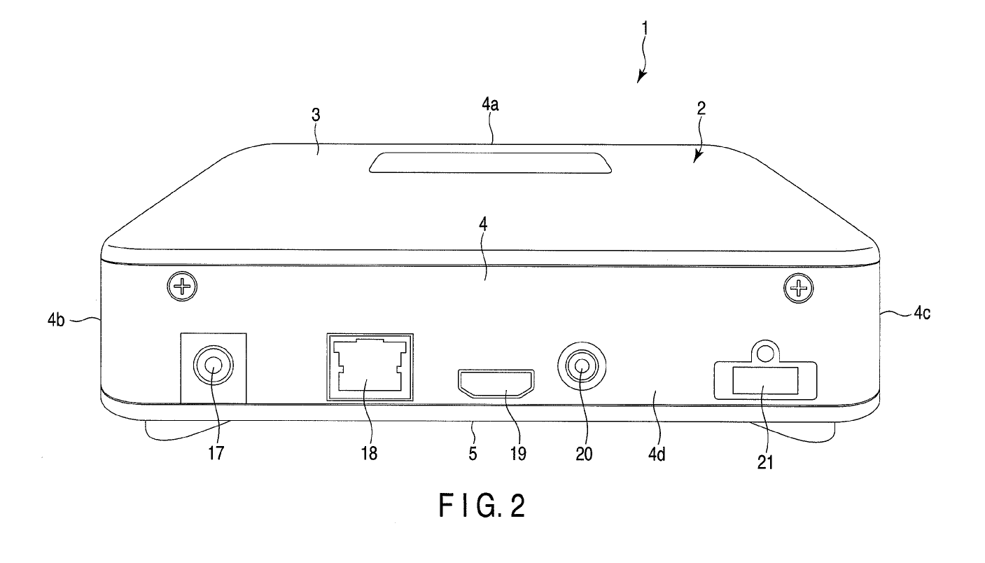

As shown in FIG. 2, a power connector 17, Local Area Network (LAN) connector 18, High-Definition Multimedia Interface (HDMI) connector 19, Audio and Visual (AV) connector 20, and Universal Serial Bus (USB) connector 21 are provided in the back wall 4d. The digital media player 1 is connected to a display apparatus such as a TV set by, for example, a cable to be connected to the HDMI connector 19. The digital media player 1 is a reproduction apparatus for displaying, for example, video data stored in the memory card 11 on the TV set or the like.

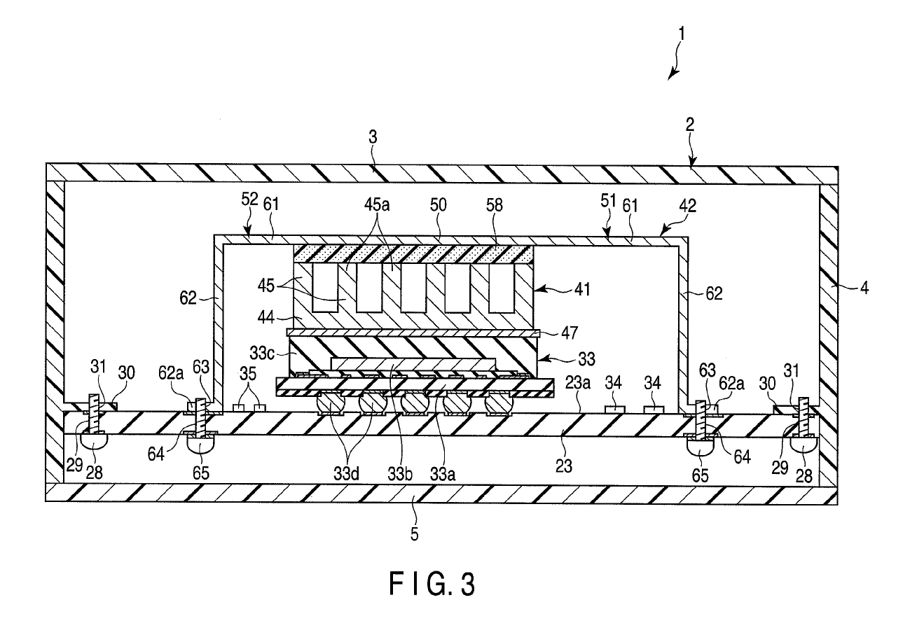

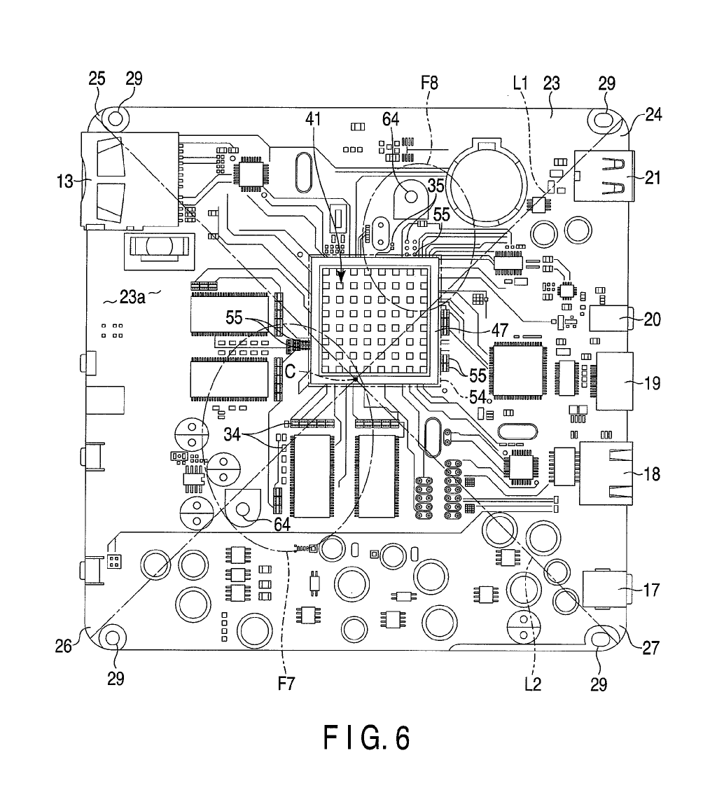

As shown in FIG. 3, the housing 2 contains a circuit board 23 therein. As shown in FIG. 6, the circuit board 23 has, for example, a quadrilateral shape in planar view and, more strictly, a substantially square shape. As shown in FIG. 3, the external shape of the circuit board 23 has a size substantially identical with a horizontal cross-sectional shape of the internal space of the housing 2.

As shown in FIG. 6, the circuit board 23 comprises four corner parts; 24, 25, 26, and 27. Insertion hole parts 29 into which screws 28 (see FIG. 3) are inserted are provided in the corner parts 24, 25, 26, and 27.

As shown in FIG. 3, the housing 2 comprises fixing parts 30 opposed to the insertion hole parts 29 of the circuit board 23. The fixing parts 30 are provided with threaded hole parts 31 with which the screws 28 are to be engaged. The screws 28 inserted into the insertion hole parts 29 of the circuit board 23 are engaged with the threaded hole parts 31 of the housing 2, whereby the circuit board 23 is fixed to the housing 2.

As shown in FIGS. 3, 5 to 8, an integrated-circuit component 33, and first and second electronic components 34, and 35 are mounted on the circuit board 23. Each of the first electronic components 34 is an example of the “electronic component” mentioned in the present invention. Each of the second electronic components 35 is an example of the “another electronic component” mentioned in the present invention.

The integrated-circuit component 33 is a component a heat generation amount of which is relatively large of the various electronic components mounted on the circuit board 23, and which is an object of heat radiation. For example, a CPU or the like corresponds to the integrated-circuit component 33. The integrated-circuit component 33 according to this embodiment 33 is a graphics-oriented component for performing, for example, processing of an image.

As shown in FIG. 3, the integrated-circuit component 33 is, for example, a semiconductor package of the Ball Grid Array (BGA) type. The integrated-circuit component 33 comprises a substrate 33a, silicon die 33b, molded resin 33c, and a plurality of bumps 33d. It should be noted that the type of the integrated-circuit component 33 is not limited to the BGA type.

As shown in FIG. 6, the integrated-circuit component 33 is mounted on the circuit board 23 at a central part thereof. Here, assuming that an intersection point C of two diagonal lines L1 and L2 connecting the corner parts 24, 25, 26, and 27 which are diagonally opposite to each other is the center of the circuit board 23, part (for example, an end part) of the integrated-circuit component 33 overlaps the center (that is, the intersection point C) of the circuit board 23.

The first and second electronic components 34 and 35 are mounted on the same board surface 23a of the circuit board 23 on which the integrated-circuit component 33 is mounted. The second electronic components 35 are mounted on the opposite side of the first electronic components 34 with respect to the integrated-circuit component 33.

The type and size of the first and second electronic components 34 and 35 are not particularly limited. The first and second electronic components 34 and 35 may be active elements such as the other integrated-circuit components, transistors, diodes, and the like, or may be passive elements such as capacitors, coils, and the like.

As shown in FIG. 3, the housing 2 contains therein a heat sink 41, and a sheet metal member 42. The heat sink 41 is an example of the “member for heat radiation” mentioned in the present invention. The heat sink 41 comprises a proximal part 44, and a plurality of pins 45 provided to stand on the proximal part 44. As shown in FIG. 6, the plurality of pins 45 are provided in a lattice-like form at intervals in the longitudinal and lateral directions. The heat sink 41 has a square shape in planar view.

As shown in FIG. 3, the heat sink 41 is opposed to the integrated-circuit component 33 with the proximal part 44 thereof directed to the integrated-circuit component 33. A thermally-conductive member 47 is interposed between the heat sink 41 and integrated-circuit component 33. The thermally-conductive member 47 is, for example a cool sheet (thermally-conductive sheet). The heat sink 41 is thermally connected to the integrated-circuit component 33 through the thermally-conductive member 47. It should be noted that the thermally-conductive member 47 may be thermally-conductive grease in place of the cool sheet.

When the digital media player 1 is used, the integrated-circuit component 33 generates heat. Part of the generated heat is conducted to the heat sink 41 through the thermally-conductive member 47, and is radiated from the heat sink 41.

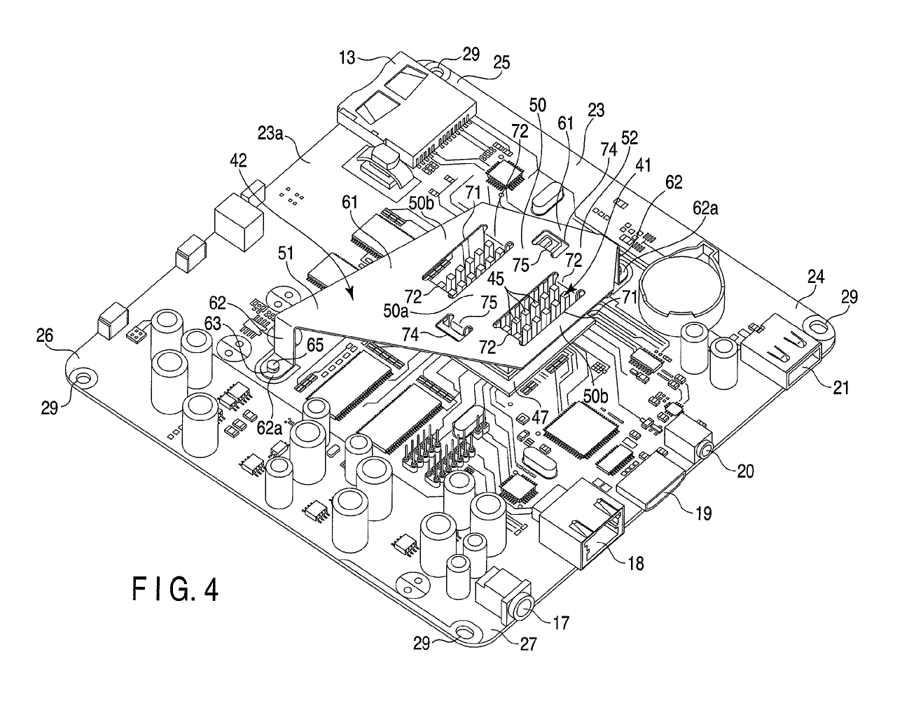

As shown in FIGS. 3 and 4, the sheet metal member 42 is a member for fastening the heat sink 41. The sheet metal member 42 comprises a main part 50, and first and second leg parts 51 and 52. The main part 50 is opposed to the heat sink 41 from the opposite side of the circuit board 23. The first and second leg parts 51 and 52 each extend from the main part 50, and are fixed to the circuit board 23 to support the main part 50.

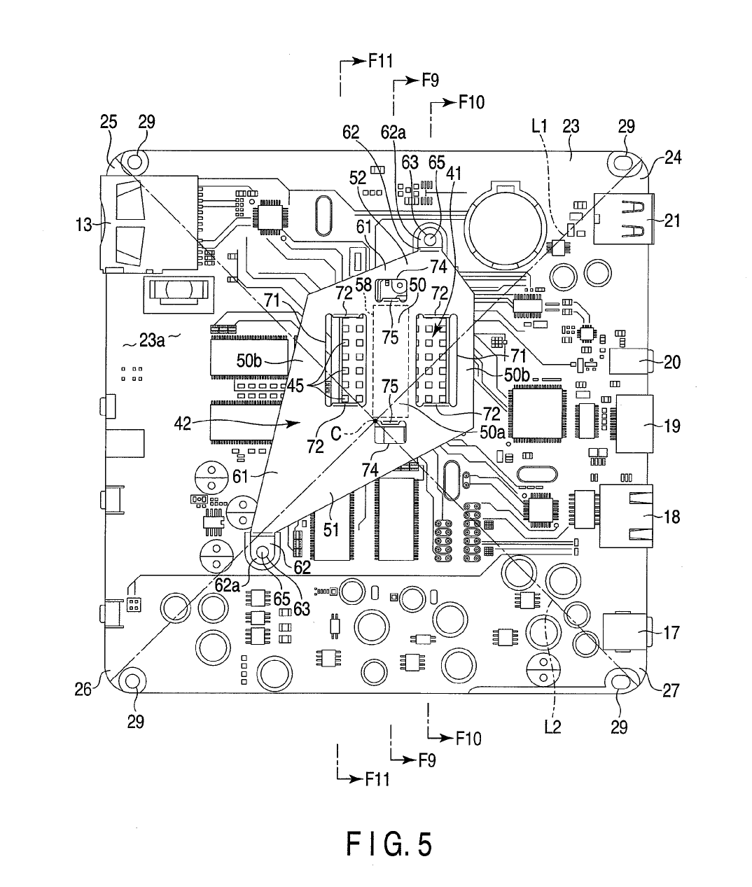

As shown in FIG. 5, the main part 50 is formed into a plate-like shape one size larger than, for example, the heat sink 41. The main part 50 has a size identical with, for example, the center core part 54 of the circuit board 23, or a size somewhat larger than the center core part 54. It should be noted that the center core part 54 implies an area a size larger than the area of the integrated-circuit component 33, and is an area covering, for example, the integrated-circuit component 33 and electronic components 55 arranged directly adjacent thereto. In this center core part 54, a circuit (so-called main circuit) associated with the integrated-circuit component 33 is wired at high density. That is, most of the wiring associated with the integrated-circuit component 33 and related components is mounted on the area covered by the sheet metal member 42 with a high density.

As shown in FIG. 5, the sheet metal member 42 is mounted on the central part of the circuit board 23. Assuming that the intersection point C of the two diagonal lines L1 and L2 connecting the corner parts 24, 25, 26, and 27 which are diagonally opposite to each other is the center of the circuit board 23, the sheet metal member 42 overlaps the center (that is, the intersection point C) of the circuit board 23.

As shown in FIG. 3, a flexible member 58 is interposed between the main part 50 of the sheet metal member 42 and the heat sink 41. The flexible member 58 is interposed between distal end parts 45a of the plurality of pins 45 of the heat sink 41 and the sheet metal member 42. An example of the flexible member 58 is a sponge member. The main part 50 presses the heat sink 41 against the integrated-circuit component 33, with the flexible member 58 interposed therebetween. As a result of this, the position of the heat sink 41 is fixed.

As shown in FIGS. 3 and 5, the first leg part 51 of the sheet metal member 42 extends from the main part 50 over, for example, the plurality of first electronic components 34. The first leg part 51 is fixed to the circuit board 23 at a position (e.g., peripheral side of the circuit board 23) which is farther from the integrated-circuit component 33 than the first electronic components 34 are. It should be noted that the first leg part 51 is an example of the “one leg part” mentioned in the present invention.

Likewise, the second leg part 52 extends from the main part 50 over, for example, the plurality of second electronic components 35. The second leg part 52 is fixed to the circuit board 23 at a position (e.g., peripheral side of the circuit board 23) which is farther from the integrated-circuit component 33 than the second electronic components 35 are. It should be noted that the second leg part 52 is an example of the “second one leg part” mentioned in the present invention.

The first and second leg parts 51 and 52 extend in directions opposite to each other with respect to the main part 50. The first leg part 51 extends from the main part 50 to the one corner part 26 side of the circuit board 23. The second leg part 52 extends from the main part 50 to the corner part 24 side diagonal to the corner part 26. The sheet metal member 42 straddles the diagonal line L2 connecting the corner parts 25 and 27 of the circuit board 23 diagonal to each other.

As shown in FIG. 6, the integrated-circuit component 33 is mounted at, for example, a position deviated from the center (intersection point C) of the circuit board 23. The integrated-circuit component 33 of this embodiment is mounted at position deviated to the corner part 24 from the center of the circuit board 23.

As shown in FIG. 5, one leg part (i.e., first leg part 51) of the first and second leg parts 51 and 52 which is located on a opposite side of a deviation side of the integrated-circuit component 33 extends farther from the main part 50 than one leg part (i.e., second leg part 52) located on the deviation side of the integrated-circuit component 33.

As shown in FIGS. 3 to 5, each of the first and second leg parts 51 and 52 comprises an extending part 61 and a fixing part 62. The extending part 61 is formed into a plate-like shape having the same thickness as the main part 50, and extends from the main part 50 in the horizontal direction. The extending part 61 has the same width as the main part 50 at a proximal part thereof, and the width thereof becomes less from the proximal part toward the fixing part 62.

The fixing part 62 extends from the distal end part of the extending part 61 toward the circuit board 23. A distal end part 62a of the fixing part 62 is bent parallel with the circuit board 23. For example, a threaded hole part 63 is provided in the distal end part 62a.

As shown in FIGS. 3 and 6, the circuit board 23 comprises insertion hole parts 64 communicating with the threaded hole parts 63 of the sheet metal member 42. When a screw 65 inserted into each of the insertion hole parts 64 is engaged with the threaded hole part 63, the sheet metal member 42 is fixed to the circuit board 23.

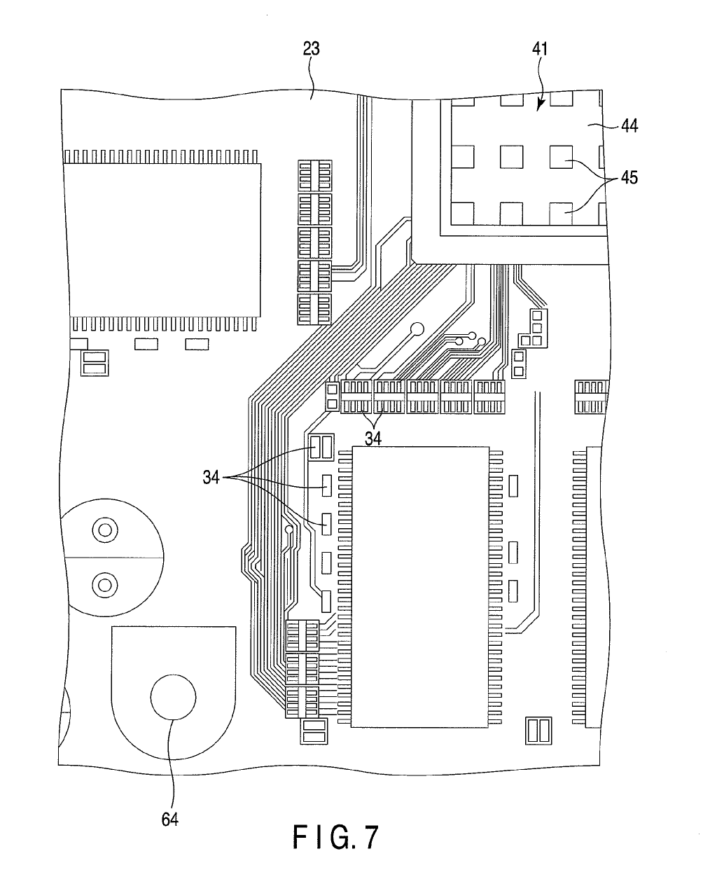

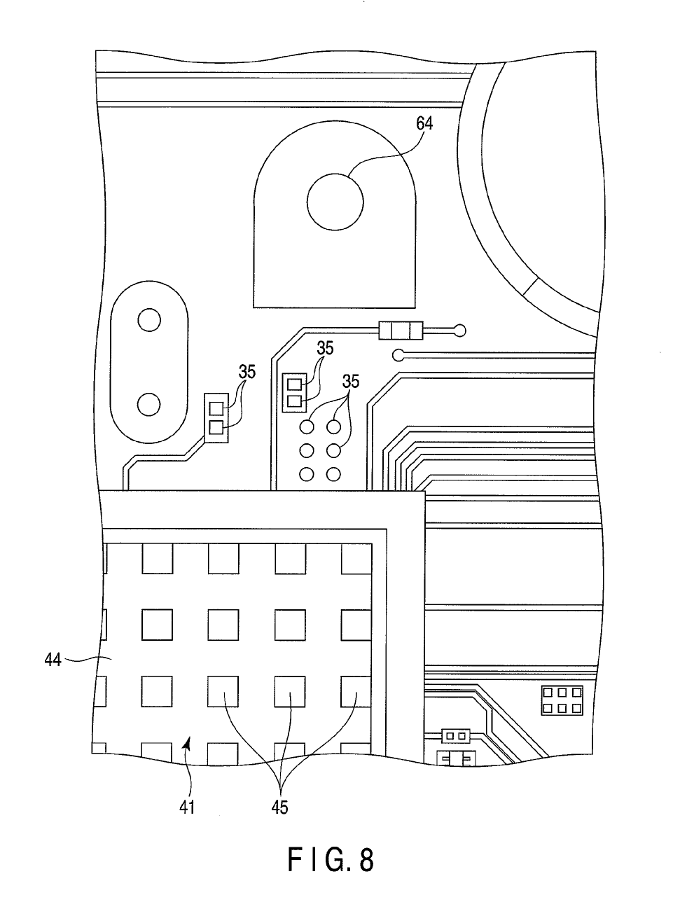

In other words, the shape of the sheet metal member 42 is a shape stretched from the center core part 54 to the insertion hole parts 64. As shown in FIG. 7, the plurality of first electronic components 34 are mounted at a part between the integrated-circuit component 33 and the insertion hole part 64 to which the first leg part 51 is fixed. As shown in FIG. 8, the plurality of second electronic components 35 are mounted at a part between the integrated-circuit component 33 and the insertion hole part 64 to which the second leg part 52 is fixed.

As shown in FIG. 5, the flexible member 58 has, for example, a rectangular shape in planar view. The width of the flexible member 58 is smaller than that of the heat sink 41. The flexible member 58 covers, for example, only the central part of the heat sink 41.

The main part 50 comprises a central part 50a opposed to (in contact with) the flexible member 58, and a pair of side parts 50b provided on both sides of the central part 50a, and off the flexible member 58. Each of the side parts 50b is provided with a first opening part 71. The first opening part 71 has a rectangular shape parallel with the flexible member 58 in the longitudinal direction of the flexible member 58. Part of the heat sink 41 is exposed to the outside of the sheet metal member 42 through the first opening parts 71.

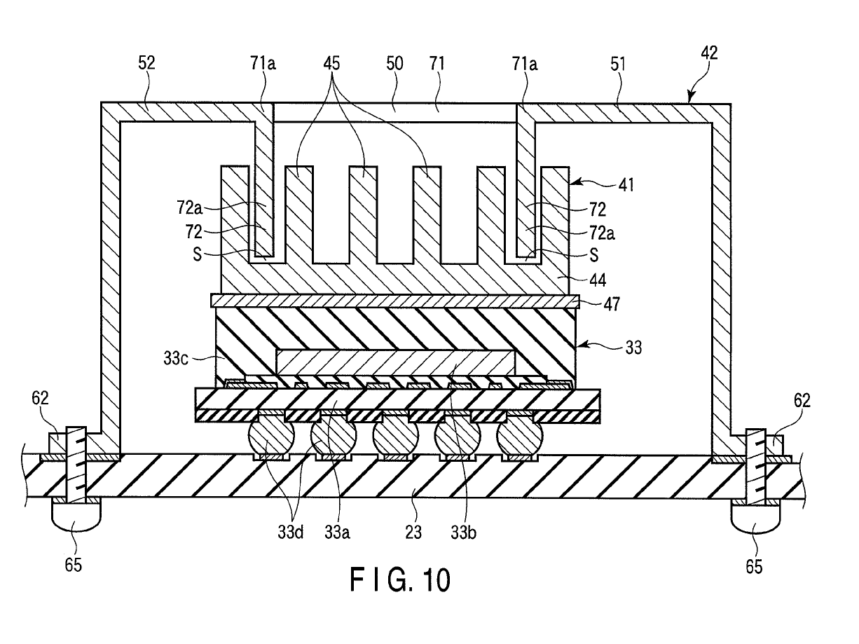

As shown in FIGS. 5 and 10, the sheet metal member 42 comprises first lug parts 72. The first lug parts 72 are provided at, for example, edge parts 71a of the first opening parts 71 in the longitudinal direction. In other words, an area formed by cutting parts corresponding to the first lug parts 72 from a sheet material and erecting the cut parts forms the first opening part 71. The first lug parts 72 are exposed to the outside of the sheet metal member 42 through the first opening part 71.

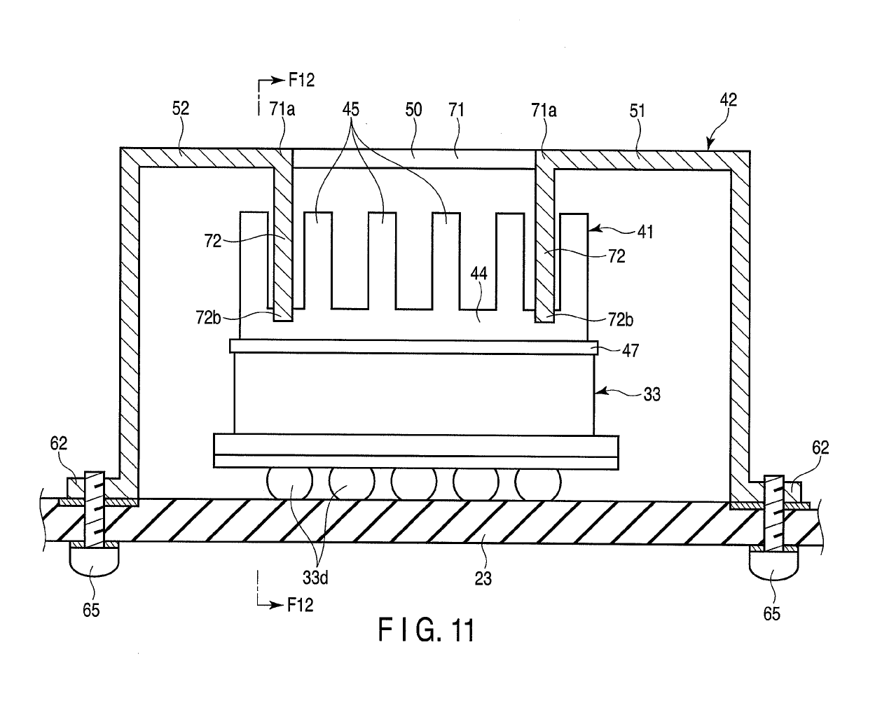

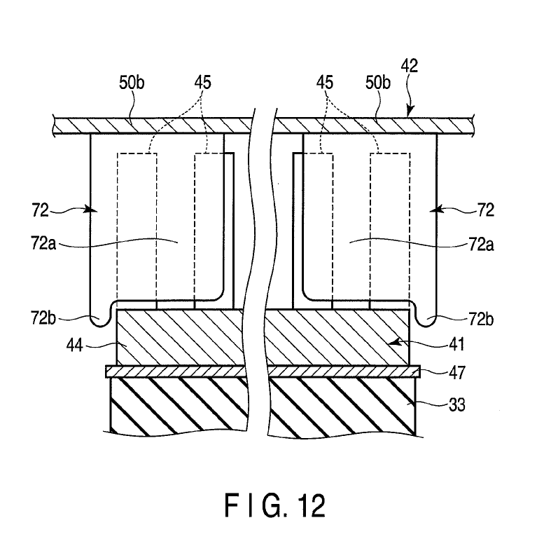

As shown in FIG. 10, the first lug part 72 protrudes from the main part 50 toward the heat sink 41, and enters spaces between pins 45 of the heat sink 41. The first lug part 72 forms a gap S between itself and the proximal part 44 of the heat sink 41. As shown in FIG. 12, the first lug part 72 comprises a main section 72a and a distal end section 72b. The main section 72a is positioned between pins 45 and pins 45, and faces pins 45. The main section 72a of the first lug part 72 fixes the position of the heat sink 41. As shown in FIGS. 11 and 12, the distal end section 72b is positioned at a lateral position of the proximal part 44 of the heat sink 41, and is opposed to the proximal part 44 of the heat sink 41 in a direction perpendicular to the direction in which the main section 72a faces the pins 45. The distal end section 72b of the first lug part 72 prevents the heat sink 41 from coming off the integrated-circuit component 33.

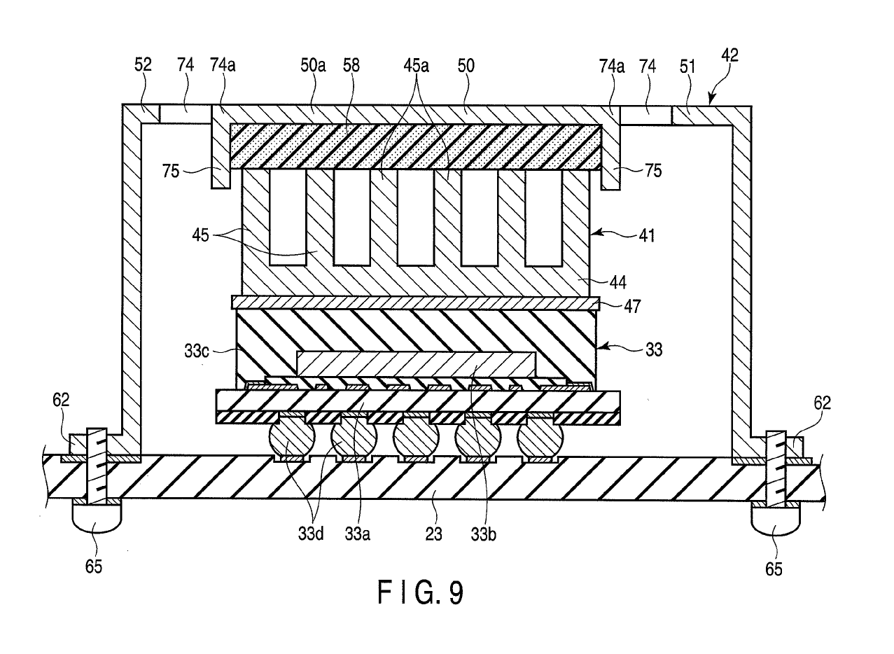

As shown in FIGS. 5 and 9, a pair of second opening parts 74 are provided in the sheet metal member 42. The second opening parts 74 are provided in front and behind the flexible member 58 in the longitudinal direction thereof. The sheet metal member 42 comprises second lug parts 75. The second lug parts 75 are provided at, for example, edge parts 74a of the second opening parts 74. In other words, an area formed by cutting a part corresponding to the second lug part 75 from a sheet material and erecting the cut part forms the second opening part 74.

As shown in FIG. 9, the pair of second lug parts 75 are opposed to the flexible member 58 from both sides of the flexible member 58 in the longitudinal direction thereof to interpose the flexible member 58 between them. The second lug parts 75 fix the position of the flexible member 58, and prevent the flexible member 58 from coming off the heat sink 41.

According to the digital media player 1 configured as described above, it is possible to reinforce the integrated-circuit component 33. That is, the first leg part 51 of the sheet metal member 42 extends from the main part 50 over the first electronic components 34, and is fixed to the circuit board 23 at a position which is farther from the integrated-circuit component 33 than the first electronic components 34 are. In other words, the leg part 51 of the sheet metal member 42 is fixed to the circuit board 23 not on the periphery (by the side of the integrated-circuit component 33) of the integrated-circuit component 33, but at a position apart from the integrated-circuit component 33. That is, the first and second leg parts 51 and 52 of the sheet metal member 42 are fixed to the circuit board 23 at positions relatively separate from each other.

When the first and second leg parts 51 and 52 are fixed to the circuit board 23 at positions relatively separate from each other, a relatively wide area of the circuit board 23 is supported by the sheet metal member 42, and hence the circuit board 23 is harder to distort (i.e., harder to be bent). In other words, the sheet metal member 42 functions not only as a fixing component for fixing the heat sink 41, but also as a reinforcing plate (i.e., back plate) for the circuit board 23.

As a result of this, even if the digital media player 1 is dropped onto a surface of a desk or floor by accident, the circuit board 23 is harder to distort by the impact, and the integrated-circuit component 33 mounted on the circuit board 23 is more resistant to breakage. That is, the digital media player 1 is improved in the drop-impact resistance and reliability. When the above-mentioned structure is applied to an electronic apparatus having a housing made of plastic of low strength, a greater effect is exhibited.

Furthermore, when the leg part 51 of the sheet metal member 42 is fixed to the circuit board 23 not on the periphery (by the side of the integrated-circuit component 33) of the integrated-circuit component 33, but at a position apart from the integrated-circuit component 33, it is not necessary to provide insertion holes or threaded holes for fixing in the peripheral part of the integrated-circuit component 33. As a result of this, it is possible to design the wiring layout without hindrance of the insertion holes or threaded holes, and arrange the wiring of the integrated-circuit component 33 and related components at high density.

When the second leg part 52 of the sheet metal member 42 extends from the main part 50 over the second electronic components 35, and is fixed to the circuit board 23 at a position which is farther from the integrated-circuit component 33 than the second electronic components 35 are, a further wider area of the circuit board 23 is reinforced by the sheet metal member 42. As a result of this, the circuit board 23 is harder to distort, and the integrated-circuit component 33 is more resistant to breakage.

When the sheet metal member 42 comprises the first lug parts 72 entering the spaces between the pin 45 and pin 45, it is possible to fix the position of the heat sink 41 by the first lug parts 72 without using other members. This contributes to simplification of the heat radiation structure, reduction in the number of components, and the like.

When the distal end section 72b of the first lug part 72 is opposed to the heat sink 41 in the direction different from the main section 72a, the position of the heat sink 41 is restrained from a plurality of directions, thus positional displacement of the heat sink 41 hardly occurs. As a result of this, it is possible to prevent the heat sink 41 from becoming detached from the integrated-circuit component 33.

When the flexible member 58 is provided between the sheet metal member 42 and the heat sink 41, it is possible to absorb the component tolerance of the integrated-circuit component 33. Further, by virtue of the presence of the flexible member 58, it is possible to use a sheet metal member 42 having a relatively low spring property. If the sheet metal member 42 having a relatively low spring property can be used, it becomes possible for the sheet metal member 42 to easily exhibit the function thereof as a reinforcing plate, and the integrated-circuit component 33 becomes more indestructible.

When the integrated-circuit component 33 is arranged at the central part (that is, substantially the center of the board) of the circuit board 23, the sheet metal member 42 is designed to cover the center of the circuit board 23, and hence it becomes easier to reinforce the circuit board 23 in its entirety by the sheet metal member 42. As a result of this, the circuit board 23 becomes harder to be distorted, and the integrated-circuit component 33 becomes more indestructible. The same is true of a case where the sheet metal member 42 straddles the diagonal line L2 connecting the corner parts 25 and 27 of the circuit board 23 diagonal to each other.

The integrated-circuit component 33 cannot be arranged to coincide with the center of the circuit board 23 in many cases due to the layout of the circuit board 23. When a sheet metal member 42 first and second leg parts of which have the same length is used for the integrated-circuit component 33 mounted at a position deviated from the center, a specific area of the circuit board 23 is reinforced. However, when the leg part 51 extending in the direction opposite to the deviation direction of the integrated-circuit component 33 extends farther from the main part 50 than the leg part 52 extending in the deviation direction of the integrated-circuit component 33, the whole (whole area) of the circuit board 23 is reinforced in a well-balanced manner. This further lessens the possibility of breakage of the integrated-circuit component 33.

When the first opening part 71 of the sheet metal member 42 exposes the heat sink 41 to the outside, heat is radiated from the heat sink more easily. That is, the heat-radiation performance of the heat sink 41 is improved. Further, when the first lug parts 72 are exposed to the outside through the first opening 71, it is possible to confirm the fixed position and fixed state of the heat sink 41 by the first lug parts 72.

The digital media player 1 according to the embodiment of the present invention has been described above. However, the present invention is not limited thereto. The constituent elements of the present invention can be modified and embodied in the implementation stage within the scope not deviating from the gist of the invention.

For example, the sheet metal member may comprise three or more leg parts. The “member for heat radiation” mentioned in the present invention is not limited to a heat sink, and may be a heat transport member such as a heat pipe. The electronic apparatus to which the present invention can be applied is not limited to a digital media player. The present invention can be applied to a video terminal electronic apparatus such as a DVD player and the like, and other electronic apparatuses.

While certain embodiments of the inventions have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. An electronic apparatus comprising:
a housing;
a circuit board in the housing comprising a heating component;
a heat radiator thermally connected to the heating component and comprising a plurality of pins; and
a holder comprising a pair of projections separate from each other in a direction in which the pins are arranged in line, each of the projections being inserted between a first pin and a second pin of the pins, a gap being provided between each of the projections and the heat radiator, the holder being configured to allow the heat radiator to be shifted between said pair of projections.

2. The electronic apparatus of claim 1, wherein the holder is a metal sheet.

3. The electronic apparatus of claim 1, further comprising a flexible portion between the holder and the heat radiator.

4. The electronic apparatus of claim 3, wherein the flexible portion is positioned between ends of the pins and the holder.

5. The electronic apparatus of claim 1, wherein the heat radiator comprises a proximal portion from which the pins stand, and each of the projections comprises a main portion facing the first pin and an end portion facing the proximal portion.

6. The electronic apparatus of claim 5, wherein the main portion of the projection faces the first pin in a first direction in which the projections are arranged in line.

7. The electronic apparatus of claim 6, wherein the end portion of the projection faces the proximal portion in a second direction different from the first direction.

8. The electronic apparatus of claim 5, wherein the main portion of the projection faces the first pin in a direction substantially orthogonal to a direction in which the projection projects, and the end portion of the projection faces the proximal portion in a direction substantially orthogonal to the direction in which the projection projects and the direction in which the main portion of the projection faces the first pin.

9. The electronic apparatus of claim 5, further comprising a gap between the main portion of the projection and the heat radiator and between the end portion of the projection and the heat radiator.

10. The electronic apparatus of claim 1, wherein the holder is fixed to the circuit board.

11. The electronic apparatus comprising:
a housing;
a circuit board in the housing comprising a heating component;
a heat radiator thermally connected to the heating component and comprising a plurality of pins;
a holder comprising a pair of first projections separate from each other in a direction in which the pins are arranged in line, each of the first projections being inserted between a first pin and a second pin of the pins, a gap being provided between each of the first projections and the heat radiator, the holder being configured to allow the heat radiator to be shifted between said pair of first projections; and
a second projection arranged with one of the first projections in line in a direction different from a direction in which the first projections are arranged in line.

12. The electronic apparatus of claim 11 wherein a gap is provided between an end portion of the second projection and the heat radiator, and the holder is configured to allow the heat radiator to be shifted between end portions of the first projections and the end portion of the second projection.
